(19) United States
(12) Patent Application Publication
(10) Pub. No.: US 2026/0334010 A1
(43) Pub. Date: Oct. 22, 2026

(54) DISPLAY PANEL AND DISPLAY DEVICE

(71) Applicant: Wuhan Tianma Microelectronics Co., Ltd., Wuhan (CN)

(72) Inventor: Fanqi MENG, Wuhan (CN)

(73) Assignee: Wuhan Tianma Microelectronics Co., Ltd., Wuhan (CN)

(21) Appl. No.: 19/286,198

(22) Filed: Jul. 30, 2025

(30) Foreign Application Priority Data
Apr. 17, 2025 (CN) 202510487529.9

(51) Int. Cl. H10K 59/122

(52) U.S. Cl. CPC H10K 59/122

(57) ABSTRACT

The present application discloses a display panel and a display device, the display panel comprising: a substrate; a first conductive layer; a pixel defining layer, the pixel defining layer comprising a pixel opening; a first electrode layer, at least partially located in the pixel opening, the first electrode layer comprising a plurality of mutually insulated first electrode blocks; a first organic layer, provided between the first conductive layer and the first electrode block, the first organic layer comprising an opening exposing the first conductive layer, so that the first electrode block is connected to the first conductive layer via the opening; in a first direction and/or a second direction, an orthographic projection of the opening on the substrate is symmetrically arranged with respect to a center of an orthographic projection of the corresponding pixel opening on the substrate.

### CROSS-REFERENCE TO RELATED APPLICATION

This application claims priority to Chinese Patent Application No. 202510487529.9, filed on Apr. 17, 2025, which is hereby incorporated by reference in its entirety.

### TECHNICAL FIELD

The present application relates to the technical field of electronic products, and in particular relates to a display panel and a display device.

### BACKGROUND

With the advancement of technology, digital display panels such as smartphones and tablet computers have been widely used, and the display screen is an indispensable interpersonal communication interface in these display panels. OLED (Organic Light-Emitting Diode) display panels have the advantages of self-light-emitting, energy-saving, consumption reduction, bendability, and good flexibility. In addition, such display panels for realizing display do not require a backlight source, have the characteristics of fast response speed and good display effect, have attracted the attention of users, and are widely used in terminal products such as smartphones and tablet computers.

However, due to the structural limitations of existing display panels, the display effect of the display panels cannot meet the requirements.

Therefore, a new display panel and display device are urgently needed.

### SUMMARY

Embodiments of the present application provide a display panel and a display device, which improve the symmetry and flatness of the first conductive layer in the area corresponding to the pixel openings, by limiting the orthographic projection of the opening on the substrate to be symmetrical with respect to the center of the orthographic projection of the corresponding pixel opening on the substrate in a first direction and/or a second direction, thereby improving the display effect of the display panel.

In a first aspect, embodiments of the present application provide a display panel, comprising: a substrate; a first conductive layer, provided on a side of the substrate; a pixel defining layer, provided on a side of the first conductive layer away from the substrate, the pixel defining layer comprises pixel openings; a first electrode layer at least partially located in the pixel openings, the first electrode layer comprises a plurality of first electrode blocks that are insulated from each other; a first organic layer provided between the first conductive layer and the first electrode blocks, the first organic layer comprises openings, the first conductive layer is exposed via the openings so that the first electrode blocks are connected to the first conductive layer via the openings; an orthographic projection of the opening on the substrate is symmetrically arranged with respect to a center of an orthographic projection of a corresponding pixel opening on the substrate in a first direction and/or a second direction intersecting with the first direction, and the first direction and the second direction are both parallel to a plane where the substrate is located.

In a second aspect, embodiments of the present application provides a display device, comprising a display panel in any of the above embodiments.

### BRIEF DESCRIPTION OF THE DRAWINGS

In order to more clearly illustrate the technical solutions of the embodiments of the present application, the drawings required for use in the embodiments of the present application are briefly described below. Obviously, the drawings described below are only some embodiments of the present application. For ordinary skilled in the art, other drawings can be obtained based on these drawings without creative work.

FIG. 1 is a schematic structural diagram of a display panel provided in an embodiment of the present application;

FIG. 2 is a partial schematic diagram of portion A in FIG. 1 provided in an embodiment of the present application;

FIG. 3 is a schematic top view of portion A in FIG. 1 provided in an embodiment of the present application;

FIG. 4 is a schematic structural diagram of a display panel provided in another embodiment of the present application;

FIG. 5 is a partial schematic diagram of portion B in FIG. 4 provided in an embodiment of the present application;

FIG. 6 is a schematic diagram of relative positions of a first electrode layer, a first organic layer, and a first conductive layer provided in an embodiment of the present application;

FIG. 7 is a schematic diagram of relative positions of a first electrode layer, a first organic layer, and a first conductive layer provided in another embodiment of the present application;

FIG. 8 is a schematic diagram of relative positions of a first electrode layer, a first organic layer, and a first conductive layer provided in yet another embodiment of the present application;

FIG. 9 is a schematic structural diagram of a display panel provided in yet another embodiment of the present application;

FIG. 10 is a schematic diagram of relative positions of a first electrode layer, a first organic layer, and a first conductive layer provided in yet another embodiment of the present application;

FIG. 11 is a schematic diagram of relative positions of a first electrode layer, a first organic layer, and a first conductive layer provided in yet another embodiment of the present application;

FIG. 12 is a schematic structural diagram of a display panel provided in yet another embodiment of the present application;

FIG. 13 is a schematic top view of a portion E in FIG. 12 provided in an embodiment of the present application;

FIG. 14 is a schematic top view of a portion J in FIG. 12 provided in an embodiment of the present application; and

FIG. 15 is a schematic structural diagram of a display device provided in an embodiment of the present application.

### DETAILED DESCRIPTION

The features and exemplary embodiments of various aspects of the present application will be described in detail below. In the detailed description below, many specific details are proposed to provide a comprehensive understanding of the present application. However, it is obvious to those skilled in the art that the present application can be implemented without the need for some of these specific details. The following description of the embodiments is only to provide a better understanding of the present application by illustrating examples of the present application.

It should be noted that, herein, relational terms such as first and second, etc. are only used to distinguish one entity or operation from another entity or operation, and do not necessarily require or imply any such actual relationship or order between these entities or operations. Moreover, the terms “include”, “comprise” or any other variants thereof are intended to cover non-exclusive inclusion, so that a process, method, article or device comprising a series of elements comprises not only those elements, but also other elements not explicitly listed, or also comprises elements inherent to such process, method, article or device. In the absence of further restrictions, the elements defined by the statement “include . . . ” do not exclude the existence of other identical elements in the process, method, article or device comprising the elements.

In the prior art, in order to realize signal transmission for the first electrode block in the display panel, it is necessary to extend the first electrode block with an additional part in a direction away from the pixel opening so as to be electrically connected to the first conductive layer via a via hole in the first organic layer provided under the first electrode block. However, the inventors have found through experimental research that the above-mentioned arrangement will cause the flatness of the film layer in the light-emitting area corresponding to the pixel opening to fail to meet the requirements, thereby affecting the light output effect of the display panel.

In order to solve the above problems, in the display panel provided in the embodiments of the present application, the symmetry and flatness of the first conductive layer in the area corresponding to the pixel opening and the display effect of the display panel are improved by connecting the symmetrically arranged via holes and the first conductive layer in the area corresponding to the pixel opening, without the need to additionally extend the first electrode layer and the first conductive layer to be electrically connected in the area outside the pixel opening.

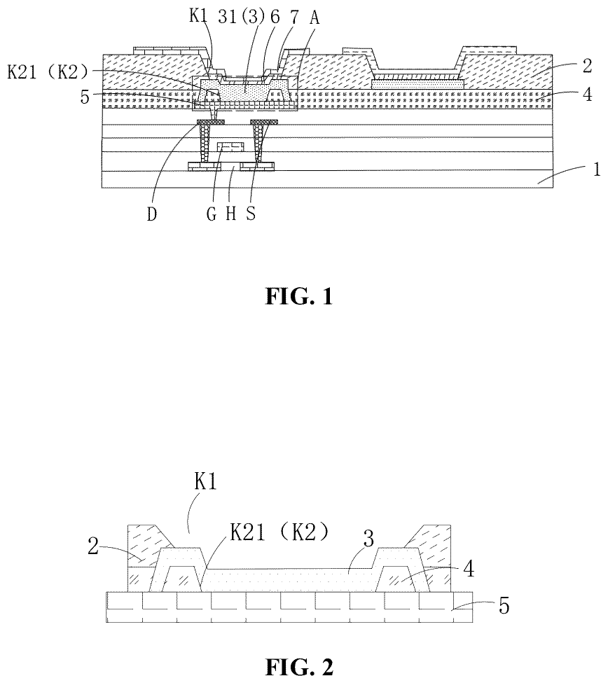

In order to better understand the present application, a display panel and a display device according to embodiments of the present application are described in detail below with reference to FIGS. 1 to 15.

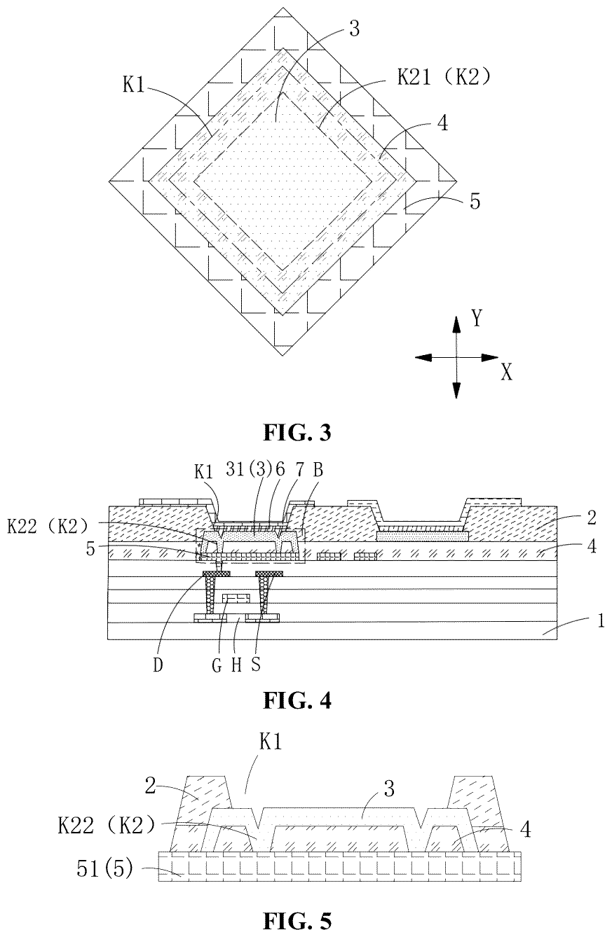

Please refer to FIGS. 1 to 3, FIG. 1 is a structural schematic diagram of a display panel provided in an embodiment of the present application; FIG. 2 is a partial schematic diagram of portion A in FIG. 1 provided in an embodiment of the present application; FIG. 3 is a top view schematic diagram of portion A in FIG. 1 provided in an embodiment of the present application.

Embodiments of the present application provide a display panel, comprising: a substrate 1; a first conductive layer 5, provided on a side of the substrate 1; a pixel defining layer 2, provided on a side of the first conductive layer 5 away from the substrate 1, the pixel defining layer 2 comprising pixel openings K1; a first electrode layer 3 at least partially located in the pixel openings K1, the first electrode layer 3 comprising a plurality of first electrode blocks 31 that are insulated from each other; and a first organic layer 4, provided between the first conductive layer 5 and the first electrode layer 3, the first organic layer 4 comprising openings K2 which expose the first conductive layer 5 so that the first electrode blocks 31 are connected to the first conductive layer 5 via the openings K2. An orthographic projection of the opening K2 on the substrate 1 is symmetrical with respect to a center of an orthographic projection of a corresponding pixel opening K1 on the substrate 1 in a first direction X and/or a second direction Y intersecting with the first direction X, and the first direction X and the second direction Y are both parallel to a plane where the substrate 1 is located.

The display panel provided by the embodiments of the present application comprises a substrate 1, a first conductive layer 5, a pixel defining layer 2, a plurality of first electrode blocks 31, and a first organic layer 4. The first organic layer 4 is provided with openings K2 so that the first electrode blocks 31 are electrically connected to the first conductive layer 5 via the openings K2. By limiting the orthographic projection of the opening K2 on the substrate 1 to be symmetrical with respect to the center of the orthographic projection of the corresponding pixel opening K1 on the substrate 1 in the first direction X and/or the second direction Y, that is, the first electrode blocks can be connected to the first conductive layer 5 in the area corresponding to the pixel opening K1 via the symmetrically arranged via holes, without the need to additionally extend the first electrode block 31 and the first conductive layer 5 to be electrically connected in the area outside the pixel openings K1, the symmetry and flatness of the first conductive layer 5 in the area corresponding to the pixel openings K1 is improved, the flatness of the light-emitting layer 6 located on the side of the first conductive layer 5 away from the substrate 1 is thereby improved, ensuring the consistency of light output at each position of the pixel openings K1, avoiding color difference and other problems caused by the unevenness of the bottom first conductive layer 5, and improving the display effect of the display panel.

It should be noted that the orthographic projection of the opening K2 on the substrate 1 is symmetrical with respect to the center of the orthographic projection of the corresponding pixel opening K1 on the substrate 1 in the first direction X and/or the second direction Y, by which it is specifically meant that the orthographic projection of the opening K2 on the substrate 1 can be symmetrical with respect to the center of the orthographic projection of the corresponding pixel opening K1 on the substrate 1 only in the first direction X, and for example, in the case that the first direction X refers to the horizontal direction in the figures, the orthographic projections of the openings K2 on the substrate 1 are up-down symmetrically arranged with respect to the center of the orthographic projection of the corresponding pixel opening K1 on the substrate 1; or that the orthographic projections of the openings K2 on the substrate 1 are symmetrically arranged with respect to the center of the orthographic projection of the corresponding pixel opening K1 on the substrate 1 only in the second direction Y, where the second direction Y may refer to the vertical direction in the figures; or that in both the first direction X and the second direction Y, the orthographic projections of the openings K2 on the substrate 1 are symmetrically arranged with respect to the center of the orthographic projection of the corresponding pixel opening K1 on the substrate 1. For example, the openings K2 may be each provided in a circular shape or the like around the center of the orthographic projection of the corresponding pixel opening K1 on the substrate 1.

Correspondingly, the orthographic projection of the first conductive layer 5 in the pixel opening K1 on the substrate 1 can be symmetrically arranged with respect to the center of the orthographic projection of the corresponding pixel opening K1 on the substrate 1. Since a part of the first electrode block 31 needs to extend into the via hole to be electrically connected to the first conductive layer 5, the structural symmetry of the first electrode block 31 with respect to the center of the corresponding pixel opening K1 can also be achieved in the first direction X and/or the second direction Y, thereby improving the uniformity of the light-emitting effect by limiting the orthographic projection of the opening K2 on the substrate 1 to be symmetrically arranged with respect to the center of the orthographic projection of the corresponding pixel opening K1 on the substrate 1 in the first direction X and/or the second direction Y.

The area corresponding to the pixel opening K1, i.e., the light-emitting effective area, can be symmetrically arranged in the first direction X and/or the second direction Y by opening in the above-mentioned manner, and the first conductive layer 5 is provided beneath the first organic layer 4 of the opening K2 to support it, which is beneficial to the planarization of the film layer in the area corresponding to the pixel opening K1.

Optionally, the first direction X is perpendicular to the second direction Y.

In this embodiment, the substrate 1 can be a rigid substrate, such as a glass substrate, or a flexible substrate, and its material can be polyimide, polystyrene, polyethylene terephthalate, polyparaxylene, polyethersulfone, or polyethylene naphthalate. The substrate 1 is mainly configured to support the device provided thereon.

Optionally, a light-emitting layer 6 and a second electrode layer 7 are stacked on a side of the first electrode block 31 facing away from the substrate 1.

Optionally, the light-emitting layer 6 comprises one or more of an electron injection layer, an electron transport layer, a hole blocking layer, a light-emitting material layer, an electron blocking layer, a hole transport layer, or a hole injection layer. The specific type of the light-emitting layer 6 can be selected without special limitation. The electron injection layer, the electron transport layer, and the hole blocking layer can be provided between the second electrode layer 7 and the light-emitting material layer. The electron blocking layer, the hole transport layer, and the hole injection layer can be provided between the first electrode block 31 and the light-emitting material layer.

The material of the first electrode block 31 is generally a material with a high work function to improve the hole injection efficiency, and may be gold (Au), platinum (Pt), titanium (Ti), silver (Ag), indium tin oxide (ITO, Indium Tin Oxide), zinc tin oxide (IZO), or a transparent conductive polymer (such as polyaniline), etc. For example, the first electrode block 31 can be made of an ITO-Ag-ITO composite material, without special limitation.

The material of the second electrode layer 7 can be one of the metal materials such as silver (Ag), aluminum (Al), lithium (Li), magnesium (Mg), ytterbium (Yb), calcium (Ca), or indium (In), and can also be an alloy of the aforementioned metal materials, such as magnesium-silver alloy (Mg/Ag) and lithium-aluminum alloy (Li/Al), which is not limited in this embodiment.

Optionally, both the pixel defining layer 2 and the first organic layer 4 each may include organic materials. For example, the material of either the pixel defining layer 2 or the first organic layer 4 may be hexamethyldisiloxane, epoxy resin, or polyimide (PI), or may be other silicone-based adhesive materials with a light transmittance of more than 90%, or other organic adhesive materials with a slightly lower light transmittance (greater than 80%) and a slightly higher bending strength. This embodiment does not impose any limitation on this.

According to actual needs, the pixel defining layer 2 can also be made of inorganic materials without special limitation.

Optionally, the first conductive layer 5 can be made of metal materials, such as molybdenum, titanium, aluminum, silver, and other metal materials, or other materials. For example, the first conductive layer 5 can be made of ITO (Indium Tin Oxide) material. ITO has high light transmittance and can effectively improve the light transmittance of the display panel to ensure the display effect.

Please refer to FIGS. 1 to 3. In some optional embodiments, the orthographic projection of the opening K2 on the substrate 1 is a solid figure.

It can be understood that since the orthographic projection of the opening K2 on the substrate 1 is a solid figure, in order to achieve the orthographic projection of the opening K2 on the substrate 1 symmetrically arranged with respect to the center of the orthographic projection of the corresponding pixel opening K1 on the substrate 1 in the first direction X and/or the second direction Y, the opening K2 whose orthographic projection is a solid figure needs to cover the center of the orthographic projection of the pixel opening K1 on the substrate 1, and the center of the orthographic projection of the opening K2 on the substrate 1 coincides with the center of the orthographic projection of the pixel opening K1 on the substrate 1.

For example, the orthographic projection figure of the opening K2 on the substrate 1 can be circular, rectangular, or other shape. It should be noted that in the first direction X and the second direction Y, in the case that the orthographic projection of the opening K2 on the substrate 1 is symmetrically arranged with respect to the center of the orthographic projection of the corresponding pixel opening K1 on the substrate 1, the orthographic projection figure of the opening K2 on the substrate 1 needs to be a centrally symmetrical pattern to achieve a symmetrical arrangement in the first direction X and the second direction Y.

Optionally, the orthographic projection of the pixel opening K1 on the substrate 1 is rectangular, and the orthographic projection of the opening K2 on the substrate 1 is correspondingly rectangular and is provided concentrically with the orthographic projection of the pixel opening K1. The edges of the orthographic projection of the rectangular opening K2 on the substrate 1 are correspondingly provided in parallel to the edges of the orthographic projection of the rectangular pixel opening K1 on the substrate 1.

The orthographic projection figure of the pixel opening K1 on the substrate 1 and the orthographic projection figure of the opening K2 on the substrate 1 may also be other shapes and are not limited to the above embodiments. The orthographic projection figure of the pixel opening K1 on the substrate 1 and the orthographic projection figure of the opening K2 on the substrate 1 may be different figures. For example, in the case that the orthographic projection figure of the pixel opening K1 on the substrate 1 is rectangular, the orthographic projection figure of the opening K2 on the substrate 1 may be circular.

Please refer to FIGS. 1 to 3. In some optional embodiments, the openings K2 comprise a first sub-hole K21. The orthographic projection of the first sub-hole K21 on the substrate 1 is at least one of a polygon or a curved-edge shape.

In this embodiment, the first sub-hole K21 corresponds to the opening K2 whose orthographic projection on the substrate 1 is a solid figure. The orthographic projection of the first sub-hole K21 on the substrate 1 is a polygon, for example, quadrilaterals such as a rectangle, a rhombus, or a shape having more straight edges such as a pentagon, a hexagon. In the case that the orthographic projection of the first sub-hole K21 on the substrate 1 is a curved-edge shape, it can specifically include a circle, an ellipse, etc., which are completely formed by curved edges, as well as a curved trapezoid or a similar shape comprising at least one curved edge.

In some optional embodiments, a ratio of the orthographic projection area of the opening K2 on the substrate 1 to the orthographic projection area of the corresponding pixel opening K1 on the substrate 1 is greater than or equal to 2:3. Alternatively, the ratio of the orthographic projection area of the opening K2 on the substrate 1 to the orthographic projection area of the corresponding pixel opening K1 on the substrate 1 is less than or equal to 1:3.

It should be noted that the first electrode block 31 may include a part located in the opening K2 and another part outside the opening K2. Due to the existence of the opening K2, there is a certain height difference between the two parts. In this embodiment, the size of the opening K2 can be adjusted to maximize the part of the first electrode block 31 located at the opening K2 or to maximize the another part of the first electrode block 31 outside the opening K2, so as to improve the overall flatness of the first electrode block 31 and reduce the impact of the opening K2 on the flatness of the first electrode block 31.

In this embodiment, in the case that the ratio of the orthographic projection area of the opening K2 on the substrate 1 to the orthographic projection area of the corresponding pixel opening K1 on the substrate 1 is greater than or equal to 2:3, correspondingly, the proportion of the part of the first electrode block 31 that sinks and extends into the opening K2 is larger. The larger the proportion of the part of the first electrode block 31 that sinks and extends into the opening K2, the smaller the proportion of the another part of the first electrode block 31, and the smaller the impact on the overall flatness of the first electrode block 31 due to the height difference between the two.

Optionally, the ratio of the orthographic projection area of the opening K2 on the substrate 1 to the orthographic projection area of the corresponding pixel opening K1 on the substrate 1 can be equal to 2:3, 3:4, 4:5, 5:6, 7:8, etc., which can be selected specifically according to actual process requirements.

Similarly, in the case that the ratio of the orthographic projection area of the opening K2 on the substrate 1 to the orthographic projection area of the corresponding pixel opening K1 on the substrate 1 is less than or equal to 1:3, since the opening K2 is small, the proportion of the corresponding part of the first electrode block 31 that sinks and extends into the opening K2 is smaller. The larger the proportion of the part of the first electrode block 31 that sinks and extends into the opening K2, the greater the difference between the two proportions, and the better the overall flatness of the first electrode block 31.

Optionally, the ratio of the orthographic projection area of the opening K2 on the substrate 1 to the orthographic projection area of the corresponding pixel opening K1 on the substrate 1 can be equal to 1:3, 1:4, 1:5, 1:6, 1:8, etc., which can be selected specifically according to actual process requirements.

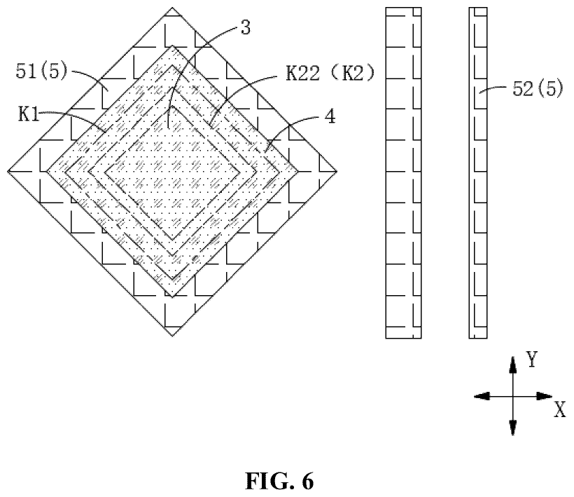

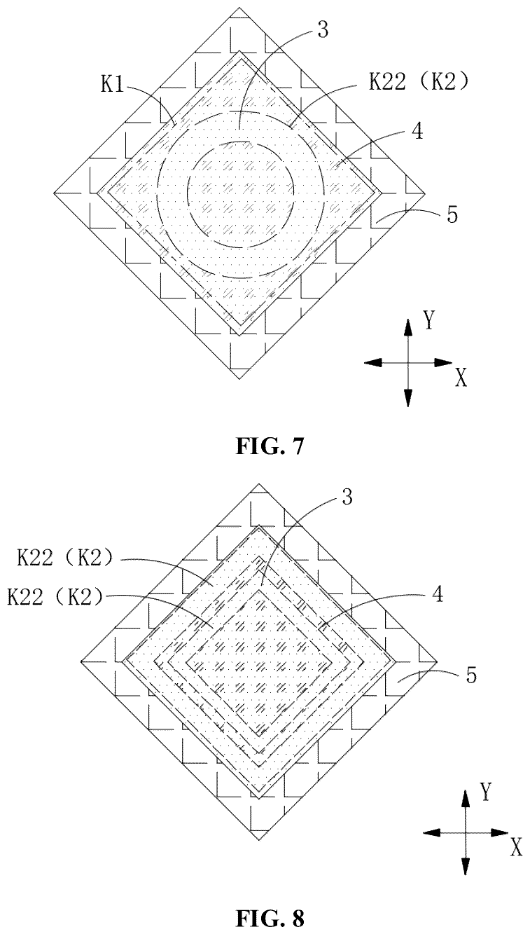

Please refer to FIGS. 4 to 7. FIG. 4 is a schematic structural diagram of a display panel provided in another embodiment of the present application; FIG. 5 is a partial schematic diagram of portion B in FIG. 4 provided in an embodiment of the present application; FIG. 6 is a schematic diagram of the relative positions of a first electrode block 31, a first organic layer 4, and a first conductive layer 5 provided in an embodiment of the present application; FIG. 7 is a schematic diagram of the relative positions of a first electrode block 31, a first organic layer 4, and a first conductive layer 5 provided in another embodiment of the present application.

In some optional embodiments, the openings K2 comprise a second sub-hole K22, and the orthographic projection of the second sub-hole K22 on the first conductive layer 5 is a in the shape of a ring.

It is noted that, the ring in this embodiment can be a closed ring structure or a ring structure with an opening, and the orthographic projection of the second sub-hole K22 on the first conductive layer 5 needs to be provided at least partially around the center of the orthographic projection of the pixel opening K1 on the substrate 1 to ensure symmetry.

Please refer to FIGS. 6 and 7. Optionally, the orthographic projection of the second sub-hole K22 on the substrate 1 is in the shape of a rectangular ring or a circular ring. Correspondingly, the orthographic projection figure of the pixel opening K1 on the substrate 1 can be rectangular or circular, that is, the orthographic projection figure of the pixel opening K1 on the substrate 1 can match the orthographic projection figure of the second sub-hole K22 on the substrate 1, which is convenient for preparation. For example, in the case that the orthographic projection figure of the pixel opening K1 on the substrate 1 is rectangular, the orthographic projection of the second sub-hole K22 on the substrate 1 is in the shape of a rectangular ring. Alternatively, the orthographic projection figure of the pixel opening K1 on the substrate 1 can also be different from the orthographic projection figure of the second sub-hole K22 on the substrate 1. For example, in the case that the orthographic projection figure of the pixel opening K1 on the substrate 1 is rectangular, the orthographic projection of the second sub-hole K22 on the substrate 1 is in the shape of a circular ring.

Please refer to FIG. 8, which is a schematic diagram of the relative positions of the first electrode block 31, the first organic layer 4, and the first conductive layer 5 provided in another embodiment of the present application. In some optional embodiments, the first organic layer 4 comprises at least two circles of second sub-holes K22 corresponding to one first electrode block 31, which are concentrically provided.

It is understandable that the more the number of circles of the second sub-holes K22 are set, the larger the contact area between the first electrode block 31 and the first conductive layer 5, and the better the electrical connection effect. However, considering that the first electrode block 31 corresponding to the second sub-hole K22 will sink, the more the number of circles of the second sub-holes K22 are set, the more the flatness of the first electrode block 31 as a whole may be affected, and the more the flatness of the light-emitting layer 6 thereon may be affected. Therefore, the number of circles of the second sub-holes K22 should not be too great. Optionally, the first organic layer 4 comprises two, three, or four circles of second sub-holes K22 corresponding to one first electrode block 31, which are concentrically arranged to ensure the symmetry of the second sub-holes K22 and to facilitate unified preparation and reduce the difficulty of preparation.

Please refer to FIG. 8. Optionally, the first organic layer 4 comprises at least two circles of second sub-holes K22 in a rectangular shape.

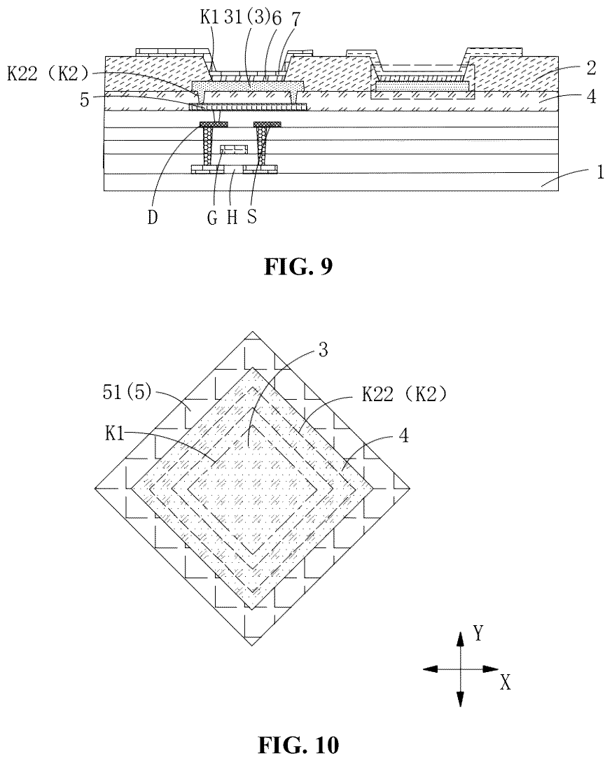

Please refer to FIGS. 9 and 10. FIG. 9 is a schematic structural diagram of a display panel provided in another embodiment of the present application; FIG. 10 is a schematic diagram of the relative positions of a first electrode block 31, a first organic layer 4, and a first conductive layer 5 provided in another embodiment of the present application. In some optional embodiments, the pixel opening K1 does not overlap with the second sub-hole K22 in a direction perpendicular to the plane where the substrate 1 is located.

It can be understood that the size of the first electrode block 31 is usually larger than the size of the pixel opening K1. In order to avoid affecting the flatness of the first electrode block 31, the light-emitting layer 6, and other film layers within the pixel opening K1 due to the opening of the second sub-hole K22, the present embodiment limits that the pixel opening K1 does not overlap with the second sub-hole K22 in the direction perpendicular to the plane where the substrate 1 is located, that is, the second sub-hole K22 is opened on the first organic layer 4 outside the pixel opening K1, and the first electrode blocks 31 and the first conductive layer 5 are connected and conducted via the second sub-holes K22 outside the pixel opening K1 to improve the light output effect at the pixel opening K1.

Optionally, the orthographic projection of the second sub-hole K22 on the substrate 1 is provided around the orthographic projection of the pixel opening K1 on the substrate 1 in a direction perpendicular to the plane where the substrate 1 is located, that is, the size of the second sub-hole K22 is larger than that of the pixel opening K1.

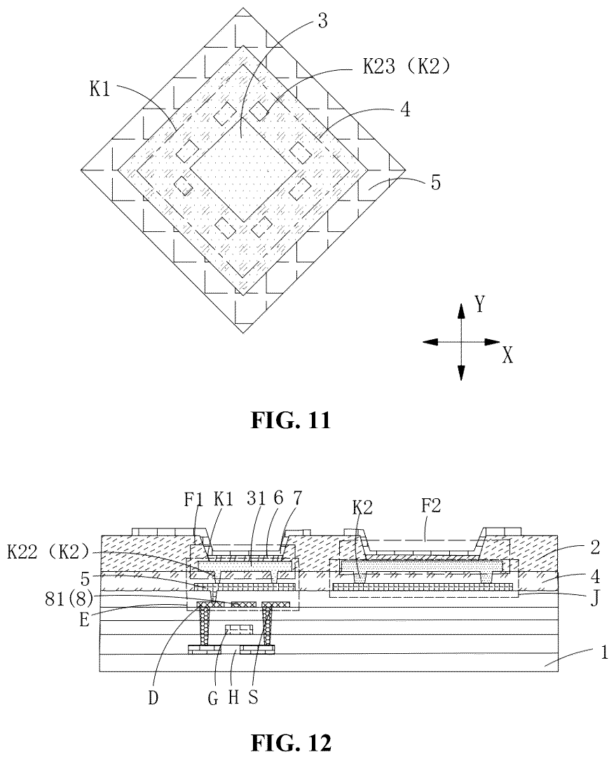

Please refer to FIG. 11, which is a schematic diagram of the relative positions of the first electrode block 31, the first organic layer 4, and the first conductive layer 5 provided in yet another embodiment of the present application. In some optional embodiments, the first organic layer 4 comprises a plurality of third sub-holes K23 provided at intervals around the center of the first electrode block 31, and lines connecting the centers of the plurality of third sub-holes K23 form a polygon or a circle.

It should be noted that, in this embodiment, the third sub-holes K23 are provided at intervals and discontinuously. The number of the third sub-holes K23 can be an even number, for example, two, four, six, eight, etc., so that the orthographic projections of the third sub-holes K23 on the substrate 1 are symmetrically arranged with respect to the center of the orthographic projection of the corresponding pixel opening K1 on the substrate 1 in the first direction x and/or the second direction Y.

The lines connecting the centers of the third sub-holes K23 form a polygonal or circular shape, that is, the third sub-holes K23 can be arranged in a ring. For example, the lines connecting the centers of the third sub-holes K23 form a rectangle, and the centers of the third sub-holes K23 are all located on the edges of the virtual rectangle to improve the regularity and symmetry of the third sub-holes K23.

Optionally, in an extension direction of edges of the figure formed by the lines connecting the centers of the third sub-holes K23, the distances between adjacent third sub-holes K23 are equal, thereby improving the uniformity of the distribution of the third sub-holes K23.

In some optional embodiments, the orthographic projection of the third sub-hole K23 on the substrate 1 is at least one of a polygon or a curved-edge shape.

Optionally, the orthographic projection of the third sub-hole K23 on the substrate 1 is in the shape of a polygon, for example, quadrilaterals such as a rectangle, a rhombus, or other shapes having more straight edges, such as a pentagon, a hexagon. In the case that the orthographic projection of the third sub-hole K23 on the substrate 1 is a curved-edge shape, it may specifically include a circle, an ellipse, or other shapes completely formed by curved edges, as well as a curved trapezoid or a similar shape comprising at least one curved edge.

It should be noted that the above-mentioned embodiments provide three different forms of openings K2, namely, the first sub-hole K21, the second sub-hole K22, and the third sub-hole K23. Any one of the first sub-hole K21, the second sub-hole K22, and the third sub-hole K23 can be applied to the first organic layer 4 provided in this embodiment, or any two or all three of the first sub-hole K21, the second sub-hole K22, and the third sub-hole K23 can be applied to the first organic layer 4 provided in this embodiment at the same time, which can be selected according to actual needs without special limitation.

Please refer to FIG. 6. In some optional embodiments, the first conductive layer 5 comprises a first conductive block 51. The orthographic projection of the first conductive block 51 on the substrate 1 covers the orthographic projection of the pixel opening K1 on the substrate 1. The first electrode block 31 and the first conductive block 51 are electrically connected via the opening K2.

In this embodiment, the first conductive block 51 is configured to be electrically connected to the first electrode block 31 to transmit a voltage signal to the first electrode block 31. The orthographic projection of the first conductive block 51 on the substrate 1 covers the orthographic projection of the pixel opening K1 on the substrate 1; that is, the size of the first conductive block 51 is greater than or equal to the size of the pixel opening K1, so as to ensure that the first conductive block 51 is provided beneath the first electrode block 31 located in the pixel opening K1 to support it, which is conducive to planarization.

Optionally, the orthographic projection of the first conductive block 51 on the substrate 1 is symmetrically arranged with respect to the center of the orthographic projection of the corresponding pixel opening K1 on the substrate 1 in the first direction X and/or the second direction Y to facilitate connection between the first conductive block 51 and the first electrode block 31.

Please refer to FIG. 6. Optionally, the first conductive layer 5 further comprises a third conductive block 52. The third conductive block 52 and the first conductive block 51 are provided adjacent to each other for transmitting other signals.

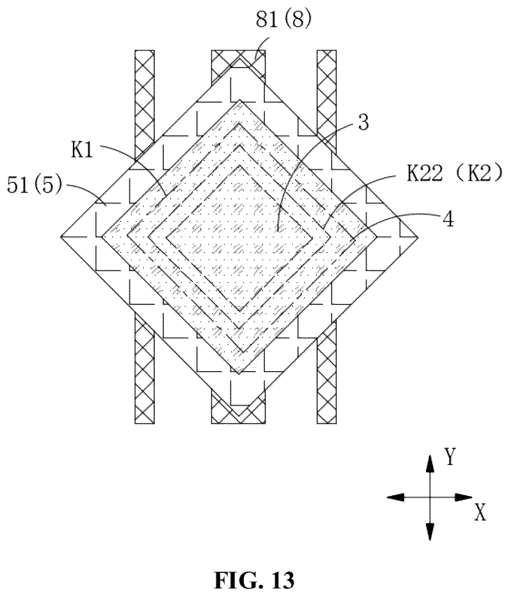

Please refer to FIGS. 12 and 13. FIG. 12 is a structural schematic diagram of a display panel provided in yet another embodiment of the present application; FIG. 13 is a top view schematic diagram of portion E in FIG. 12 provided in an embodiment of the present application. In some optional embodiments, the display panel further comprises a second conductive layer 8 located between the substrate 1 and the first conductive layer 5. The second conductive layer 8 comprises a second conductive block 81, and the second conductive block 81 and the pixel opening K1 at least partially overlap in a direction perpendicular to the plane where the substrate 1 is located. The orthographic projection of the second conductive block 81 on the substrate 1 is symmetrically arranged with respect to the center of the orthographic projection of the corresponding pixel opening K1 on the substrate 1 in the first direction X and/or the second direction Y.

It is understandable that since the display panel needs to be provided with a variety of different signal lines or devices such as transistors, the display panel usually comprises multiple conductive layers. In the present embodiment, the second conductive block 81 of the second conductive layer 8 is located beneath the first conductive block 51, and the second conductive block 81 and the pixel opening K1 at least partially overlap in the direction perpendicular to the plane of the substrate 1; that is, the symmetry of the second conductive block 81 will also affect the flatness of the inner film layers of the pixel opening K1, such as the first electrode block 31 and the light-emitting layer 6 located thereon.

In this embodiment, the orthographic projection of the second conductive block 81 on the substrate 1 is symmetrically arranged with respect to the center of the orthographic projection of the corresponding pixel opening K1 on the substrate 1 in the first direction X and/or the second direction Y, so as to further improve the symmetry and flatness of the film layers in the area corresponding to the pixel opening K1, ensure the consistency of light output at the positions of the pixel opening K1, avoid color difference and other problems caused by the unevenness of the bottom first conductive layer 5, and improve the display effect of the display panel.

In some optional embodiments, the second conductive block 81 comprises at least one of a data signal line or a power supply voltage signal line. For example, in the case that the data signal lines extend in the second direction Y and are arranged at intervals in the first direction X, the orthographic projection of the data signal line on the substrate 1 is arranged symmetrically with respect to the center of the orthographic projection of the corresponding pixel opening K1 on the substrate 1 in the first direction X and/or the second direction Y. Similarly, in the case that the power supply voltage signal lines extend in the second direction Y and are arranged at intervals in the first direction X, the orthographic projection of the power supply voltage signal line on the substrate 1 is arranged symmetrically with respect to the center of the orthographic projection of the corresponding pixel opening K1 on the substrate 1 in the first direction X and/or the second direction Y. The data signal line and the power supply voltage signal line may further extend in the first direction X or other directions without special limitation and may be provided according to actual wiring needs.

Please refer to FIG. 12. In some optional embodiments, the display panel further comprises an array layer provided between the substrate 1 and the first electrode block 31. The array layer comprises an active layer H, a gate layer G, a source layer S, a drain layer D, and a transition connection layer in the direction away from the substrate 1. Among them, the source layer S and the drain layer D are at least partially provided in the same layer, the first conductive layer 5 and the transition connection layer are provided in the same layer, and the second conductive layer 8 and the source layer S are provided in the same layer.

In this embodiment, the active layer H, the gate layer G, the source layer S, and the drain layer D can be configured to form a transistor. The materials of the source layer S and the gate layer G can include a combination of one or more of molybdenum, titanium, aluminum, and copper. The gate layer G of the transistor is usually configured to receive a control signal to turn the transistor on or off under the control of the control signal. One of the source layer S and the drain layer D of the transistor is connected to the first electrode block 31 to control the normal light emission of the light-emitting layer 6.

The transition connection layer can be configured to connect one of the source layer S and the drain layer D to the first electrode block 31. The second conductive layer 8 can be made of the same material as that of the first conductive layer 5 to reduce costs. For example, the second conductive layer 8 can be made of a metal material, such as molybdenum, titanium, aluminum, silver, etc., or other materials. For example, the second conductive layer 8 can also be made of ITO (Indium Tin Oxide) material. ITO has high light transmittance, which can effectively improve the light transmittance of the display panel and ensure the display effect.

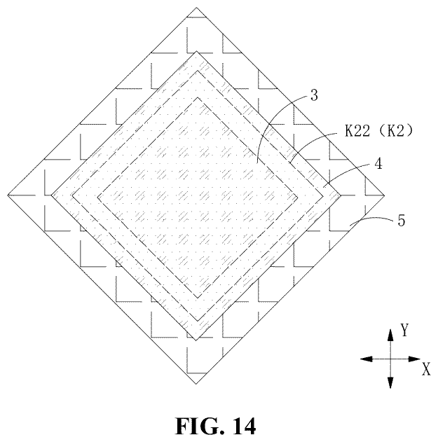

Please refer to FIGS. 12 to 14. FIG. 14 is a schematic top view of portion J in FIG. 12 provided in an embodiment of the present application. In some optional embodiments, the display panel comprises a first light-emitting structure F1 and a second light-emitting structure F2 with different light-emitting colors. The first light-emitting structure F1 and the second light-emitting structure F2 each include the first electrode block 31, and the orthographic projection area of the first electrode block 31 of the first light-emitting structure F1 is different from that of the second light-emitting structure F2 on the substrate 1. The orthographic projection area of the openings K2 of the first organic layer 4 corresponding to the first light-emitting structure F1 is different from the orthographic projection area of the openings K2 of the first organic layer 4 corresponding to the second light-emitting structure F2 on the substrate 1.

It should be noted that, taking into account the requirements of pixel arrangement and other aspects, the light-emitting area of the first light-emitting structure F1 may be different from that of the second light-emitting structure F2. Correspondingly, the orthographic projection area of the first electrode block 31 in the first light-emitting structure F1 is also different from the orthographic projection area of the first electrode block 31 in the second light-emitting structure F2 on the substrate 1. In the present embodiment, the size of the corresponding opening K2 of the first organic layer 4 can be adjusted according to the size of the first electrode block 31. That is, the orthographic projection area of the opening K2 of the first organic layer 4 corresponding to the first light-emitting structure F1 on the substrate 1 is different from the orthographic projection area of the opening K2 of the first organic layer 4 corresponding to the second light-emitting structure F2 on the substrate 1, as shown in FIGS. 13 and 14, to ensure that the first electrode blocks 31 of different sizes can be effectively connected to the corresponding first conductive layer 5 via the opening K2.

For example, in the case that the orthographic projection area of the first electrode block 31 of the first light-emitting structure F1 on the substrate 1 is larger than the orthographic projection area of the first electrode block 31 of the second light-emitting structure F2 on the substrate 1, the size of the opening K2 corresponding to the first light-emitting structure F1 can be increased accordingly. That is, the orthographic projection area of the opening K2 of the first organic layer 4 corresponding to the first light-emitting structure F1 on the substrate 1 is larger than the orthographic projection area of the opening K2 of the first organic layer 4 corresponding to the second light-emitting structure F2 on the substrate 1, so as to increase the contact area between the first electrode block 31 in the first light-emitting structure F1 and the first conductive layer 5.

Similarly, please refer to FIGS. 13 to 14. If the orthographic projection area of the first electrode block 31 in the first light-emitting structure F1 on the substrate 1 is smaller than the orthographic projection area of the first electrode block 31 in the second light-emitting structure F2 on the substrate 1, the size of the opening K2 corresponding to the second light-emitting structure F2 can be increased accordingly. That is, the orthographic projection area of the opening K2 of the first organic layer 4 corresponding to the first light-emitting structure F1 on the substrate 1 is smaller than the orthographic projection area of the opening K2 of the first organic layer 4 corresponding to the second light-emitting structure F2 on the substrate 1, so as to increase the contact area between the first electrode block 31 in the second light-emitting structure F2 and the first conductive layer 5.

Optionally, the display panel further comprises a third light-emitting structure with a light-emitting color different from that of the first light-emitting structure F1 or the second light-emitting structure F2. The light-emitting area of the third light-emitting structure can be the same as that of any one of the first light-emitting structure F1 and the second light-emitting structure F2, or can be different from that of any one of the first light-emitting structure F1 and the second light-emitting structure F2, which can be specifically selected according to actual needs and is not particularly limited. Correspondingly, the orthographic projection area of the opening K2 of the first organic layer 4 corresponding to the third light-emitting structure on the substrate 1 can also match the first electrode block 31 in the third light-emitting structure and can be increased or decreased accordingly.

Optionally, the first light-emitting structure F1, the second light-emitting structure F2, and the third light-emitting structure may each be one of a red light-emitting structure, a green light-emitting structure, or a blue light-emitting structure, respectively, to facilitate light mixing.

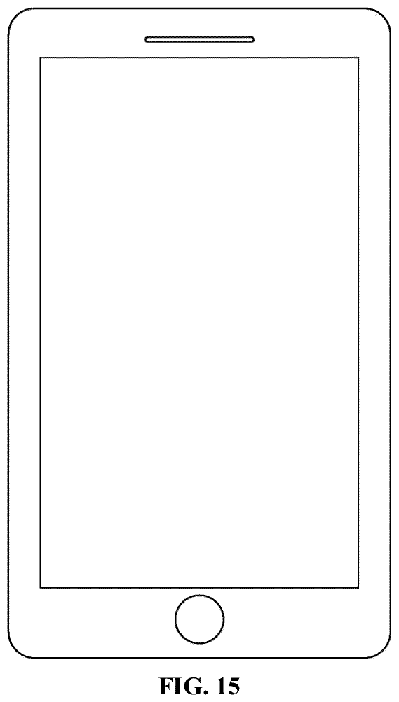

Please refer to FIG. 15. Embodiments of the present application further provide a display device comprising the display panel in any of the above embodiments.

The display device provided by the embodiment of the present application has the technical effect of the technical solution of the display panel in any of the above embodiments, and the explanation of the structures and terms that are the same as or correspond to the above embodiments will not be repeated here.

The display panel provided in the embodiments of the present application may be an organic light-emitting diode (OLED) display panel, a quantum dot light-emitting diode (QLED), or a micro flat display panel (Micro-OLED or Micro-LED).

The display device provided in the embodiments of the present application can be applied to a mobile phone, or any electronic product with a display function, comprising but not limited to the following categories: televisions, laptops, desktop displays, tablet computers, digital cameras, smart bracelets, smart glasses, car displays, medical equipment, industrial control equipment, and touch interactive terminals. The embodiments of the present application do not make any special limitations on this.

The above are only specific implementations of the present application. Those skilled in the art can clearly understand that for the convenience and simplicity of description, the specific working process of the system, module and unit described above can refer to the location process in the aforementioned method embodiment, and will not be repeated here. It should be understood that the protection scope of the present application is not limited to this. Any technician familiar with the technical field can easily think of various equivalent modifications or replacements within the technical scope disclosed by the present application, and these modifications or replacements should be covered within the protection scope of the present application.

It should also be noted that the exemplary embodiments mentioned in the present application describe some methods or systems based on a series of steps or devices. However, the present application is not limited to the order of the above steps; that is, the steps can be performed in the order mentioned in the embodiments, in a different order from the embodiments, or several steps can be performed simultaneously.

What is claimed is:

1. A display panel, comprising:
a substrate;
a first conductive layer, provided on a side of the substrate;
a pixel defining layer, provided on a side of the first conductive layer away from the substrate, the pixel defining layer comprising pixel openings;
a first electrode layer, at least partially located in the pixel openings, the first electrode layer comprising a plurality of first electrode blocks that are insulated from each other;
a first organic layer, provided between the first conductive layer and the plurality of first electrode blocks, the first organic layer comprising openings exposing the first conductive layer so that the first electrode blocks are connected to the first conductive layer via the openings;
wherein in a first direction and/or a second direction intersecting with the first direction, an orthographic projection of each of the openings on the substrate is symmetrically arranged with respect to a center of an orthographic projection of a corresponding one of the pixel openings on the substrate, the first direction and the second direction being both parallel to a plane where the substrate is located.

2. The display panel according to claim 1, wherein the orthographic projection of each of the openings on the substrate is a solid figure.

3. The display panel according to claim 2, wherein the openings comprise a first sub-hole, an orthographic projection of the first sub-hole on the substrate being in a shape of at least one of a polygon or a curved-edge shape.

4. The display panel according to claim 2, wherein a ratio of an orthographic projection area of each of the openings on the substrate to an orthographic projection area of the corresponding one of the pixel openings on the substrate is greater than or equal to 2:3, or
a ratio of the orthographic projection area of each of the openings on the substrate to the orthographic projection area of the corresponding one of the pixel openings on the substrate is less than or equal to 1:3.

5. The display panel according to claim 1, wherein the openings comprise a second sub-hole, an orthographic projection of the second sub-hole on the first conductive layer being in a shape of a ring.

6. The display panel according to claim 5, wherein the first organic layer comprises at least two of the second sub-holes that are in a concentric arrangement corresponding to one of the first electrode blocks.

7. The display panel according to claim 5, wherein an orthographic projection of the second sub-hole on the substrate is in a shape of a rectangular ring or a circular ring.

8. The display panel according to claim 5, wherein the pixel openings do not overlap with the second sub-hole in a direction perpendicular to the plane where the substrate is located.

9. The display panel according to claim 1, wherein the first organic layer comprises a plurality of third sub-holes provided at intervals around a center of at least one of the first electrode blocks, lines connecting centers of the plurality of third sub-holes forming a polygonal or a circle.

10. The display panel according to claim 9, wherein an orthographic projection of each of the plurality of third sub-holes on the substrate is in a shape of at least one of a polygon or a curved-edge shape.

11. The display panel according to claim 1, wherein the first conductive layer comprises first conductive blocks, an orthographic projection of each of the first conductive blocks on the substrate covering an orthographic projection of one of the pixel openings on the substrate; and
the first electrode blocks are electrically connected to the first conductive blocks via the openings.

12. The display panel according to claim 1, further comprising a second conductive layer located between the substrate and the first conductive layer, the second conductive layer comprising second conductive blocks, wherein
the second conductive blocks at least partially overlap with the pixel openings in the direction perpendicular to the plane where the substrate is located; and
an orthographic projection of each of the second conductive blocks on the substrate is symmetrically arranged with respect to a center of an orthographic projection of a corresponding one of the pixel openings on the substrate in the first direction and/or the second direction.

13. The display panel according to claim 12, wherein the second conductive blocks comprise at least one of a data signal line or a power voltage signal line.

14. The display panel according to claim 12, further comprising an array layer provided between the substrate and the first electrode layer,
the array layer comprising an active layer, a gate layer, a source layer, a drain layer, and a transition connection layer in a direction away from the substrate, wherein
the source layer and the drain layer are at least partially provided in a same layer; and
the first conductive layer and the transition connection layer are provided in a same layer, and the second conductive layer and the source layer are provided in a same layer.

15. The display panel according to claim 1, further comprising a first light-emitting structure and a second light-emitting structure of different light-emitting colors, the first light-emitting structure and the second light-emitting structure each comprising at least one of the first electrode blocks, wherein
an orthographic projection area of the at least one of the first electrode blocks of the first light-emitting structure on the substrate is different from an orthographic projection area of the at least one of the first electrode blocks of the second light-emitting structure on the substrate; and
an orthographic projection area of the openings of the first organic layer corresponding to the first light-emitting structure on the substrate is different from an orthographic projection area of the openings of the first organic layer corresponding to the second light-emitting structure on the substrate.

16. A display device, comprising a display panel which comprises:
a substrate;
a first conductive layer, provided on a side of the substrate;
a pixel defining layer, provided on a side of the first conductive layer away from the substrate, the pixel defining layer comprising pixel openings;
a first electrode layer, at least partially located in the pixel openings, the first electrode layer comprising a plurality of first electrode blocks that are insulated from each other;
a first organic layer, provided between the first conductive layer and the plurality of first electrode blocks, the first organic layer comprising openings exposing the first conductive layer so that the first electrode blocks are connected to the first conductive layer via the openings;
wherein in a first direction and/or a second direction intersecting with the first direction, an orthographic projection of each of the openings on the substrate is symmetrically arranged with respect to a center of an orthographic projection of a corresponding one of the pixel openings on the substrate, the first direction and the second direction being both parallel to a plane where the substrate is located.

17. The display device according to claim 16, wherein the orthographic projection of each of the openings on the substrate is a solid figure.

18. The display device according to claim 17, wherein the openings comprise a first sub-hole, an orthographic projection of the first sub-hole on the substrate being at least one of a polygon or a curved-edge shape.

19. The display device according to claim 17, wherein a ratio of an orthographic projection area of each of the openings on the substrate to an orthographic projection area of the corresponding one of the pixel openings on the substrate is greater than or equal to 2:3, or
a ratio of the orthographic projection area of each of the openings on the substrate to the orthographic projection area of the corresponding one of the pixel openings on the substrate is less than or equal to 1:3.

20. The display device according to claim 16, wherein the openings comprise a second sub-hole, an orthographic projection of the second sub-hole on the first conductive layer having a ring-shaped structure.
